(19) United States
(12) Patent Application Publication
(10) Pub. No.: US 2013/0200351 A1
(43) Pub. Date: Aug. 8, 2013

(54) POLYMER COMPOUND AND ORGANIC PHOTOELECTRIC CONVERSION DEVICE

(71) Applicants: Yasunori Uetani, Tsukuba-shi (JP); Ken Yoshimura, Tsukuba-shi (JP); Jun Fujiwara, Oita-shi (JP)

(72) Inventors: Yasunori Uetani, Tsukuba-shi (JP); Ken Yoshimura, Tsukuba-shi (JP); Jun Fujiwara, Oita-shi (JP)

(73) Assignee: SUMITOMO CHEMICAL COMPANY, LIMITED, Chuo-ku, Tokyo (JP)

(21) Appl. No.: 13/818,816

(22) PCT Filed: Aug. 23, 2011
(86) PCT No.: PCT/JP2011/069366

§ 371 Date: Apr. 18, 2013

(30) Foreign Application Priority Data
Sep. 10, 2010 (JP) 2010-202799
Dec. 10, 2010 (JP) 2010-275431

(51) Int. Cl. H01L 51/00; H01L 51/42

(52) U.S. Cl. CPC H01L 51/0036; H01L 51/42
USPC 257/40; 526/239

(57) ABSTRACT

A polymer compound comprising a repeating unit represented by the formula (1) is useful for an organic photoelectric conversion device:

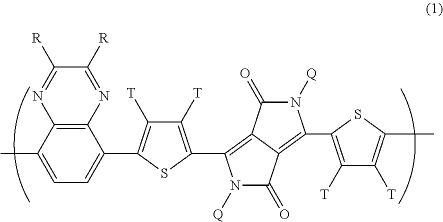

[wherein, Q, R and T are the same or different and represent a hydrogen atom, a fluorine atom, an alkyl group optionally substituted by a fluorine atom, an alkoxy group optionally substituted by a fluorine atom, an optionally substituted aryl group, an optionally substituted heteroaryl group or a group represented by the formula (2). Two Qs may be the same or different. Two Rs may be the same or different. Four Ts may be the same or different.

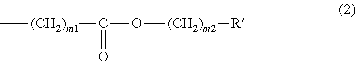

(wherein, m1 represents an integer of 0 to 6 and m2 represents an integer of 0 to 6. R′ represents an alkyl group, an optionally substituted aryl group or an optionally substituted heteroaryl group.)].

### TECHNICAL FIELD

The present invention relates to a polymer compound and an organic photoelectric conversion device using the same.

### BACKGROUND ART

Organic semiconductor materials are expected to be applied to organic photoelectric conversion devices such as organic solar batteries, optical sensors and the like. Particularly, if a polymer compound is used as the organic semiconductor material, a functional layer can be fabricated by an inexpensive coating method. For improving the properties of an organic photoelectric conversion device, there are investigations of use of organic semiconductor materials which are various polymer compounds in an organic photoelectric conversion device. As the organic semiconductor material, there is a suggestion, for example, on a polymer compound obtained by polymerizing 9,9-dioctylfluorene-2,7-diboronic acid ester and 5,5″″-dibromo-3″,4″-dihexyl-α-pentathiophene (WO2005/092947).

### SUMMARY OF THE INVENTION

The above-described polymer compound, however, manifests insufficient absorption of long-wavelength light.

Therefore, the present invention provides a polymer compound showing large absorbance of long-wavelength light.

That is, the present invention provides a polymer compound comprising a repeating unit represented by the formula (1).

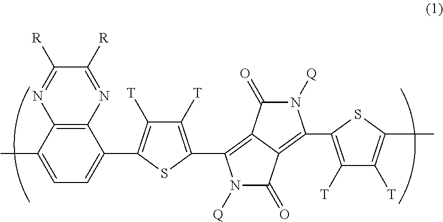

[wherein, Q, R and T are the same or different and represent a hydrogen atom, a fluorine atom, an alkyl group optionally substituted by a fluorine atom, an alkoxy group optionally substituted by a fluorine atom, an optionally substituted aryl group, an optionally substituted heteroaryl group or a group represented by the formula (2). Two Qs may be the same or different. Two Rs may be the same or different. Four Ts may be the same or different.

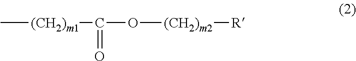

(wherein, m1 represents an integer of 0 to 6 and m2 represents an integer of 0 to 6. R′ represents an alkyl group, an optionally substituted aryl group or an optionally substituted heteroaryl group.)].

Also, the present invention provides an organic photoelectric conversion device having a pair of electrodes and a functional layer disposed between the electrodes, wherein the functional layer comprises an electron accepting compound and the above-described polymer compound.

### BRIEF DESCRIPTION OF DRAWINGS

FIG. 1 is a view showing the absorption spectrum of the polymer compound 1.

FIG. 2 is a view showing the absorption spectrum of the polymer compound 2.

FIG. 3 is a view showing the absorption spectrum of the polymer compound 3.

FIG. 4 is a view showing the absorption spectrum of the polymer compound 4.

### MODES FOR CARRYING OUT THE INVENTION

The present invention will be illustrated in detail below.

The polymer compound of the present invention comprises a repeating unit represented by the formula (1) described above.

In the formula (1), the alkyl group represented by Q, R or T may be chained or cyclic, and examples thereof include a methyl group, an ethyl group, a propyl group, an isopropyl group, a butyl group, an isobutyl group, a sec-butyl group, a tert-butyl group, a pentyl group, a hexyl group, an octyl group, an isooctyl group, a decyl group, a dodecyl group, a pentadecyl group and an octadecyl group. A hydrogen atom in the alkyl group may be substituted by a fluorine atom. Examples of the alkyl group in which a hydrogen atom is substituted by a fluorine atom include a trifluoromethyl group, a pentafluoroethyl group, a perfluorobutyl group, a perfluorohexyl group and a perfluorooctyl group.

The alkyl portion in the alkoxy group represented by Q, R or T may be chained or cyclic, and specific examples of the alkoxy group include a methoxy group, an ethoxy group, a propoxy group, an isopropoxy group, a butoxy group, an isobutoxy group, a sec-butoxy group, a tert-butoxy group, a pentyloxy group, a hexyloxy group, a cyclohexyloxy group, a heptyloxy group, an octyloxy group, a 2-ethylhexyloxy group, a nonyloxy group, a decyloxy group and a 3,7-dimethyloctyloxy group. A hydrogen atom in the alkoxy group may be substituted by a fluorine atom. Examples of the alkoxy group in which a hydrogen atom is substituted by a fluorine atom include a trifluoromethoxy group, a pentafluoroethoxy group, a perfluorobutoxy group, a perfluorohexyloxy group and a perfluorooctyloxy group.

When Q, R or T represents an alkyl group or an alkoxy group, the alkyl group or alkoxy group has preferably 1 to 20, more preferably 2 to 18, further preferably 3 to 12 carbon atoms, from the standpoint of the solubility of the polymer compound in a solvent.

The aryl group represented by Q, R or T is an atomic group obtained by removing one hydrogen atom from an unsubstituted aromatic hydrocarbon, and also includes those having a benzene ring, those having a condensed ring, and those having independent two or more benzene rings or condensed rings linked directly or via a group such as vinylene and the like. The aryl group has preferably 6 to 60, more preferably 6 to 30 carbon atoms. The aryl group may have a substituent. Examples of the aryl group include a phenyl group, a 1-naphthyl group and a 2-naphthyl group. Examples of the substituent optionally carried on the aryl group include halogen atoms (a fluorine atom, a chlorine atom, a bromine atom and an iodine atom), alkyl groups having 1 to 20 carbon atoms and alkoxy groups having 1 to 20 carbon atoms.

Examples of the heteroaryl group represented by Q, R or T include a thienyl group, a pyrrolyl group, a furyl group, a pyridyl group, a quinolyl group and an isoquinolyl group. The heteroaryl group may have a substituent, and this substituent includes the same substituents as listed for the aryl group.

In the group represented by the formula (2), m1 represents an integer of 0 to 6 and m2 represents an integer of 0 to 6. R′ represents an alkyl group, an optionally substituted aryl group or an optionally substituted heteroaryl group. The definitions and specific examples of the alkyl group, optionally substituted aryl group and optionally substituted heteroaryl group represented by R′ are the same as those of the alkyl group, optionally substituted aryl group and optionally substituted heteroaryl group represented by R.

Examples of the repeating unit represented by the formula (1) include the following repeating units.

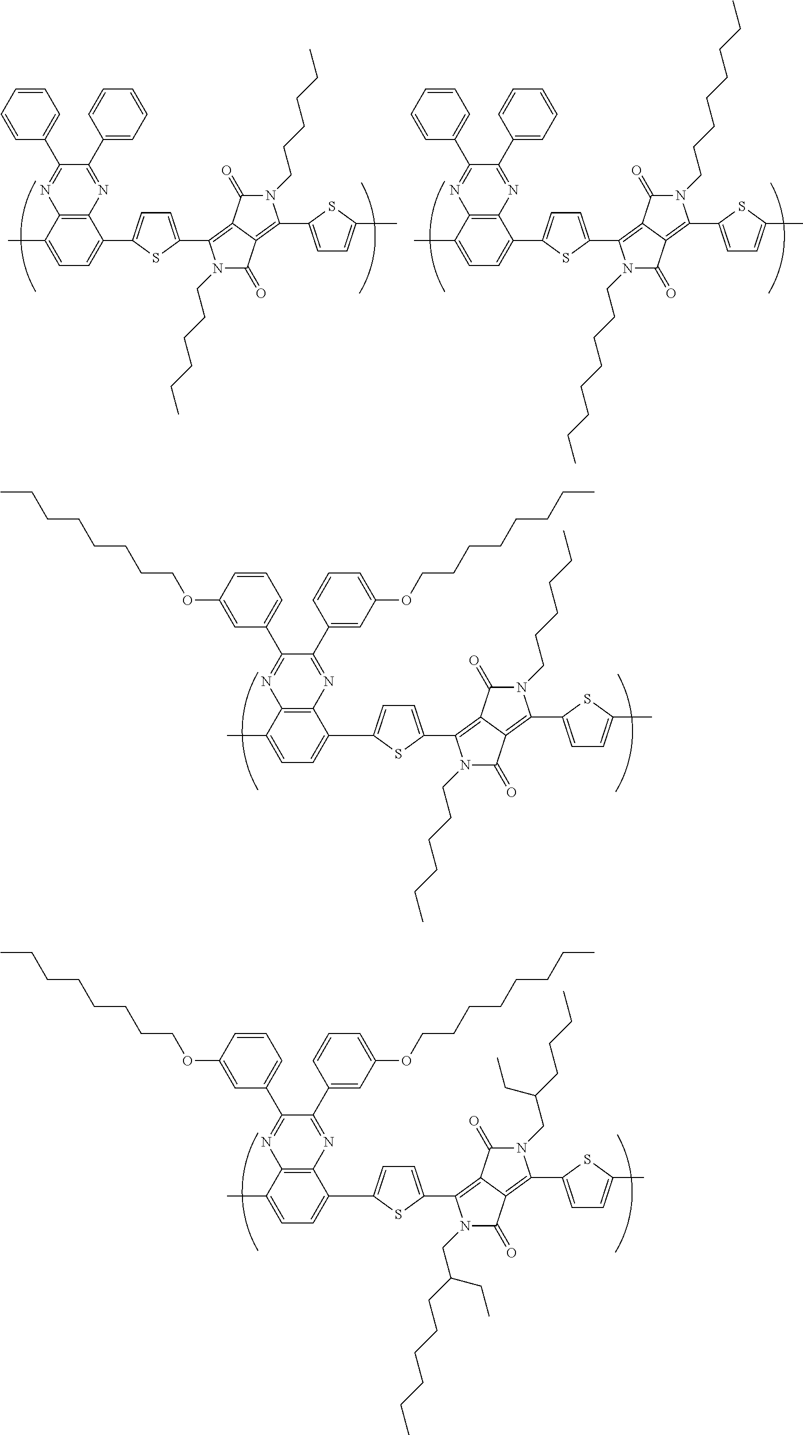

The amount of the repeating unit represented by the formula (1) comprised in the polymer compound of the present invention is preferably 20 to 100 mol %, more preferably 30 to 100 mol % with respect to the total amount of all repeating units in the polymer compound, from the standpoint of enhancement of the photoelectric conversion efficiency of an organic photoelectric conversion device having a functional layer containing the polymer compound.

The polymer compound of the present invention has a polystyrene-equivalent weight-average molecular weight of preferably 10³ to 10⁸, more preferably 10³ to 10⁷, further preferably 10³ to 10⁶.

It is preferable that the polymer compound of the present invention is a conjugated polymer compound. Here, the conjugated polymer compound means a compound in which atoms constituting the main chain of the polymer compound are conjugated.

The polymer compound of the present invention may have other repeating unit than the repeating unit represented by the formula (1). The other repeating unit than the repeating unit represented by the formula (1) includes an arylene group, a heteroarylene group and the like. The arylene group includes a phenylene group, a naphthalenediyl group, an anthracenediyl group, a pyrenediyl group, a fluorenediyl group and the like. The heteroarylene group includes a furanediyl group, a pyrrolediyl group, a pyridinediyl group and the like.

The polymer compound of the present invention may be produced by any methods and, for example, can be synthesized by synthesizing a monomer having a functional group suitable for the polymerization reaction to be used, then, dissolving the monomer in an organic solvent if necessary, and polymerizing the monomer by using a known aryl coupling reaction using an alkali, a catalyst, a ligand and the like. The above-described monomer synthesis can be performed by referring to methods disclosed, for example, in US2008/145571 and JP-A No. 2006-335933.

Polymerization by an aryl coupling reaction includes, for example, polymerization by the Suzuki coupling reaction, polymerization by the Yamamoto coupling reaction, polymerization by the Kumada-Tamao coupling reaction, polymerization by reaction with an oxidizer such as FeCl₃ and the like and oxidation polymerization by electrochemical reaction.

Polymerization by the Suzuki coupling reaction is polymerization of reacting a monomer having a boronic acid residue or a borate residue with a monomer having a halogen atom such as a bromine atom, an iodine atom, a chlorine atom and the like or with a monomer having a sulfonate group such as a trifluoromethanesulfonate group, a p-toluenesulfonate group and the like in the presence of an inorganic base or an organic base using a palladium complex or a nickel complex as a catalyst and, if necessary, with a ligand added.

Examples of the inorganic base include sodium carbonate, potassium carbonate, cesium carbonate, tripotassium phosphate and potassium fluoride. Examples of the organic base include tetrabutylammonium fluoride, tetrabutylammonium chloride, tetrabutylammonium bromide and tetraethylammonium hydroxide. Examples of the palladium complex include palladium[tetrakis(triphenylphosphine)], [tris(dibenzylideneacetone)]dipalladium, palladium acetate and bis(triphenylphosphine)palladium dichloride. Examples of the nickel complex include bis(cyclooctadiene)nickel. Examples of the ligand include triphenylphosphine, tri(2-methylphenyl)phosphine, tri(2-methoxyphenyl)phosphine, diphenylphosphinopropane, tri(cyclohexyl)phosphine and tri(tert-butyl)phosphine.

Details of polymerization by the Suzuki coupling reaction are described in, for example, Journal of Polymer Science: Part A: Polymer Chemistry, 2001, vol. 39, pp. 1533-1556.

Polymerization by the Yamamoto coupling reaction is polymerization of mutually reacting monomers having a halogen atom, mutually reacting monomers having a sulfonate group such as a trifluoromethanesulfonate group and the like, or reacting a monomer having a halogen atom with a monomer having a sulfonate group, using a catalyst and a reducing agent.

The catalyst includes catalysts composed of a nickel zero-valent complex such as bis(cyclooctadiene)nickel and the like and of a ligand such as bipyridyl and the like, and catalysts composed of a nickel complex other than the nickel zero-valent complex such as [bis(diphenylphosphino)ethane]nickel dichloride, [bis(diphenylphosphino)propane]nickel dichloride and the like and, if necessary, of a ligand such as triphenylphosphine, diphenylphosphinopropane, tri(cyclohexyl)phosphine, tri(tert-butyl)phosphine and the like. Examples of the reducing agent include zinc and magnesium. In polymerization by the Yamamoto coupling reaction, a dehydrated solvent maybe used in the reaction, the reaction may be carried out under an inert atmosphere, or a dehydrating agent may be added into the reaction system.

Details of polymerization by the Yamamoto coupling are described in, for example, Macromolecules, 1992, vol. 25, pp. 1214-1223.

Polymerization by the Kumada-Tamao coupling reaction is polymerization of reacting a compound having a halogenated magnesium group with a compound having a halogen atom under dehydration conditions using a nickel catalyst such as [bis(diphenylphosphino)ethane]nickel dichloride, [bis(diphenylphosphino)propane]nickel dichloride and the like.

In polymerization by the above-described aryl coupling reaction, a solvent is usually used. The solvent may be selected in consideration of the polymerization reaction to be used, the solubility of a monomer and a polymer, and the like. Specifically mentioned are organic solvents such as tetrahydrofuran, toluene, 1,4-dioxane, dimethoxyethane, N,N-dimethylacetamide, N, N-dimethylformamide, a mixed solvent prepared by mixing two or more of these solvents, and the like, and solvents having two phases composed of an organic solvent phase and an aqueous phase. As the solvent used in the Suzuki coupling reaction, preferable are organic solvents such as tetrahydrofuran, toluene, 1,4-dioxane, dimethoxyethane, N,N-dimethylacetamide, N, N-dimethylformamide, a mixed solvent prepared by mixing two or more of these solvents, and the like, and solvents having two phases composed of an organic solvent phase and an aqueous phase. The solvent used in the Suzuki coupling reaction is preferably subjected to a deoxygenation treatment before the reaction for suppressing side reactions. As the solvent used in the Yamamoto coupling reaction, preferable are organic solvents such as tetrahydrofuran, toluene, 1,4-dioxane, dimethoxyethane, N,N-dimethylacetamide, N,N-dimethylformamide, a mixed solvent prepared by mixing two or more of these solvents, and the like. The solvent used in the Yamamoto coupling reaction is preferably subjected to a deoxygenation treatment before the reaction for suppressing side reactions.

Among polymerization procedures by the above-described aryl coupling reaction, preferable are the method of polymerization by the Suzuki coupling reaction and the method of polymerization by the Yamamoto coupling reaction, more preferable are the method of polymerization by the Suzuki coupling reaction and the method of polymerization by the Yamamoto coupling reaction using a nickel zero-valent complex, from the standpoint of reactivity.

The lower limit of the reaction temperature of the above-described aryl coupling reaction is preferably −100° C., more preferably −20° C., particularly preferably 0° C. from the standpoint of reactivity. The upper limit of the reaction temperature is preferably 200° C., more preferably 150° C., particularly preferably 120° C. from the standpoint of the stability of a monomer and a polymer compound.

In polymerization by the above-described aryl coupling reaction, known methods are mentioned as a method for taking out the polymer compound of the present invention from the reaction solution after completion of the reaction. For example, the polymer compound of the present invention can be obtained by adding the reaction solution to a lower alcohol such as methanol and the like, filtering the deposited precipitate and drying the filtrated material. When the purity of the resultant polymer compound is low, the polymer compound can be purified by recrystallization, continuous extraction with a Soxhlet extractor, column chromatography and the like.

When the polymer compound of the present invention is used for production of an organic photoelectric conversion device, the properties of the organic photoelectric conversion device such as durability and the like sometimes lower if a polymerization active group remains at the end of the polymer compound, therefore, it is preferable that the end of the polymer compound is protected with a stable group.

The stable group for protecting the end includes an alkyl group, an alkoxy group, a fluoroalkyl group, a fluoroalkoxy group, an aryl group, an arylamino group, a mono-valent heterocyclic group and the like. The arylamino group includes a phenylamino group, a diphenylamino group and the like. The mono-valent heterocyclic group includes a thienyl group, a pyrrolyl group, a furyl group, a pyridyl group, a quinolyl group, an isoquinolyl group and the like. Further, the polymerization active group remaining at the end of the polymer compound may be substituted by a hydrogen atom instead of the stable group. It is preferable that the stable group for protecting the end is a group imparting an electron donating property such as an arylamino group and the like, from the standpoint of enhancement of hole transportability. When the polymer compound is a conjugated polymer compound, also a group having a conjugated bond so that the conjugate structure of the main chain of the polymer compound and the conjugate structure of the stable group for protecting the end are continuous can be preferably used as the stable group for protecting the end. Examples of this group include aryl groups and mono-valent heterocyclic groups having aromaticity.

In the case of production using the Suzuki coupling reaction, the polymer compound of the present invention can be produced, for example, by polymerizing a compound represented by the formula (3) and a compound represented by the formula (4). As the polymerization reaction, for example, the Suzuki coupling reaction is mentioned.

In the formula (3), the borate residue represented by Z means a group obtained by removing a hydroxyl group from a boric acid diester, and specific examples thereof include groups represented by the following formulae.

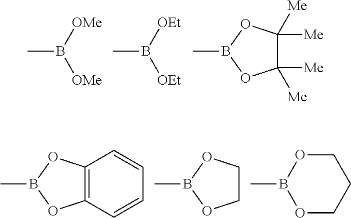

(wherein, Me represents a methyl group and Et represents an ethyl group.)

Examples of the compound represented by the formula (3) include the following compounds.

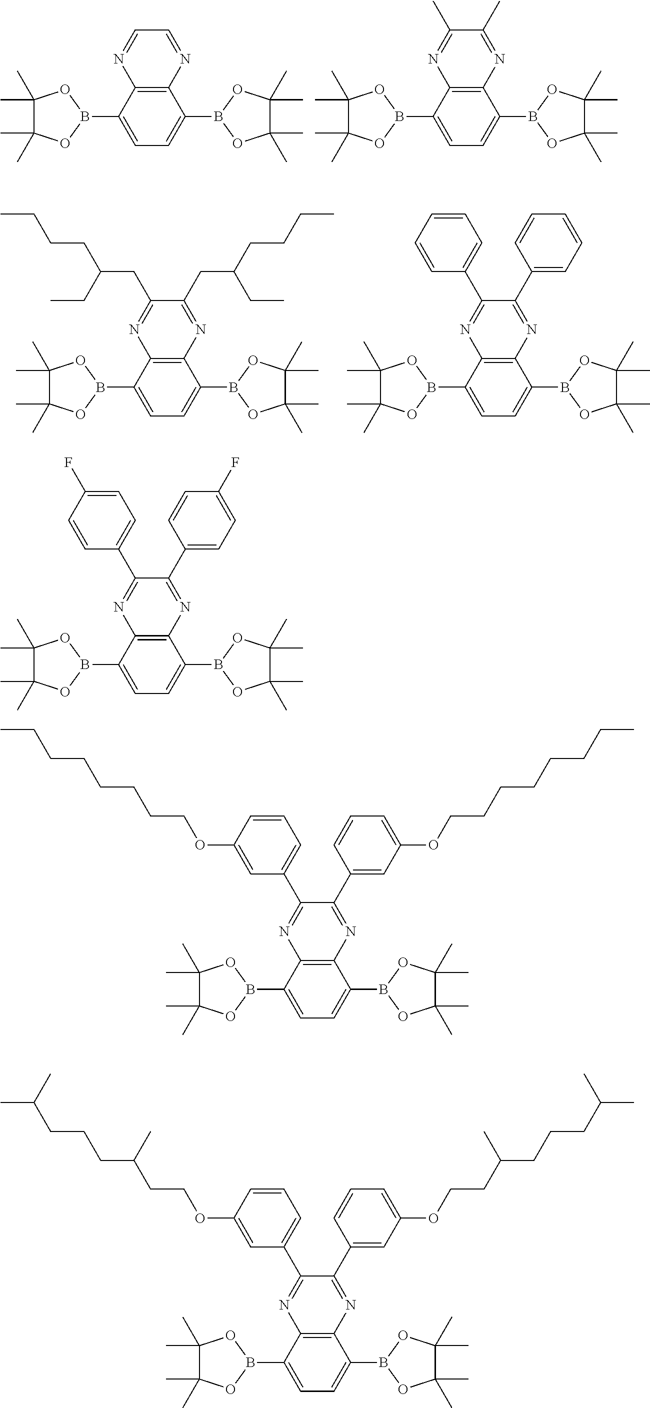

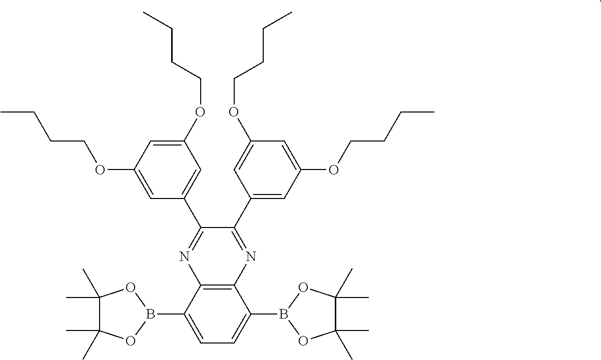 [SMILES: CCCCOc1cc(OCCCC)cc(-c2nc3c(B4OC(C)(C)C(C)(C)O4)ccc(B4OC(C)(C)C(C)(C)O4)c3nc2-c2cc(OCCCC)cc(OCCCC)c2)c1]

The compound represented by the formula (3) can be produced by dehydration-condensing a compound represented by the formula (5) with an alcohol or a diol in an organic solvent.

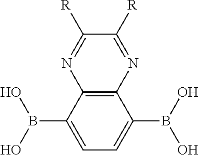

(wherein, R represents the same meaning as described above.)

In the above-described reaction, generation of the compound represented by the formula (3) can be confirmed by disappearance of a slurry compound represented by the formula (5) to give a homogeneous reaction solution. After the reaction, the reaction solution is concentrated using an evaporator, the residue is washed with a hydrocarbon solvent having relatively lower boiling point such as hexane and the like, then, filtration thereof is performed, thus, a compound represented by the formula (3) can be obtained.

Examples of the alcohol used in the above-described reaction include methanol, ethanol, propanol, 2-propanol and butanol.

Examples of the diol which can be used in the above-described reaction include pinacol, catechol, ethylene glycol and 1,3-propane diol.

In the above-described, a dehydrating agent such as anhydrous magnesium sulfate, anhydrous sodium sulfate and the like may also be added.

Examples of the compound represented by the formula (5) include the following compounds.

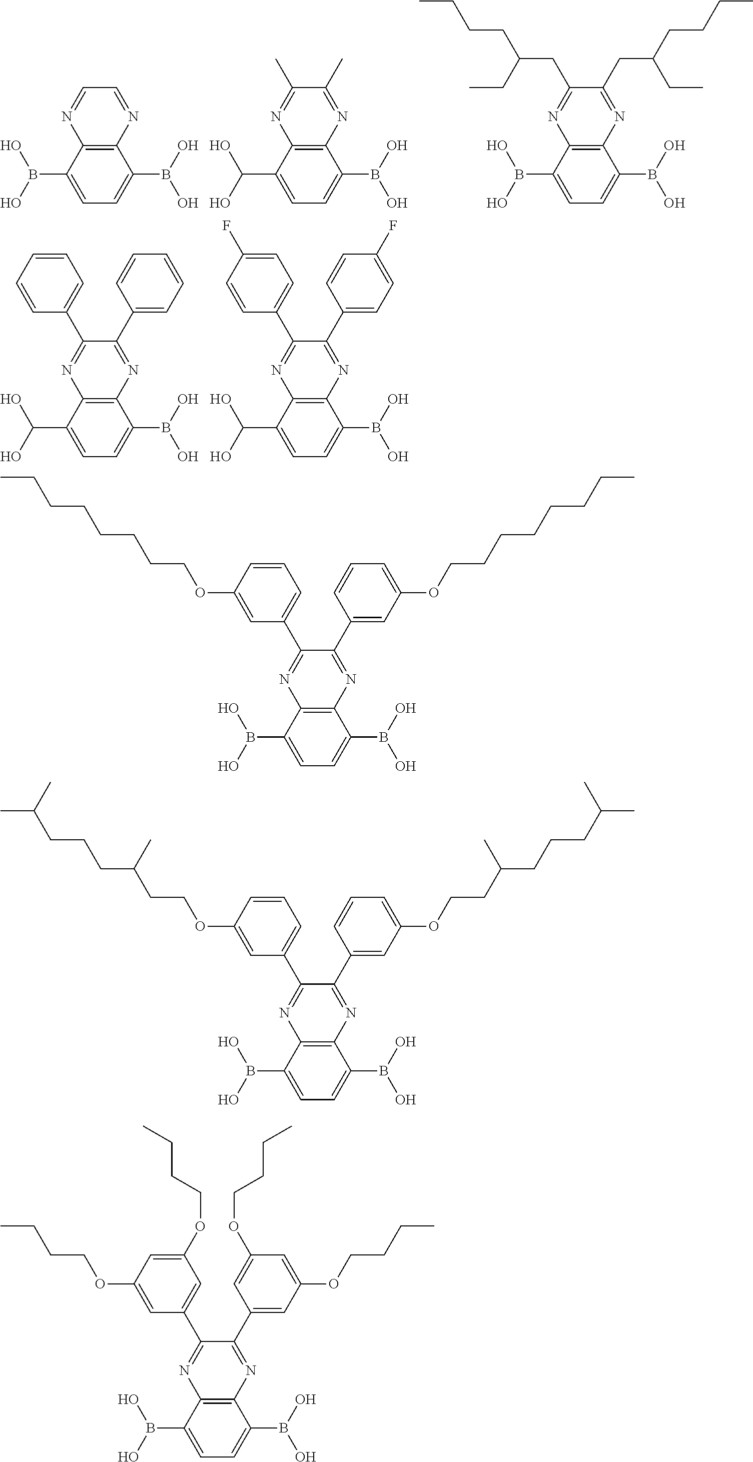

The compound represented by the formula (5) can be produced by lithiating a compound represented by the formula (6) with an organolithium compound such as butyllithium (n-BuLi) and the like, thereafter, reacting the lithiated compound with a borate such as trimethyl borate (trimethoxyborane) and the like to produce a compound represented by the formula (7), and acid-treating the compound represented by the formula (7) with an acid such as dilute hydrochloric acid and the like.

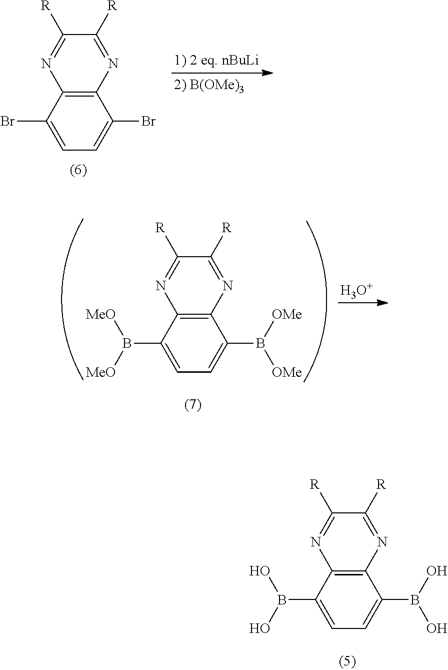

(wherein, R represents the same meaning as described above.)

The above-described lithiation reaction is usually carried out in an anhydrous ether solvent such as anhydrous tetrahydrofuran, anhydrous diethyl ether and the like. The reaction temperature is usually −80° C. to 25° C., depending on the kind of the compound represented by the formula (6) as a reactive substrate. Examples of the acid used in the above-described acid-treatment include hydrochloric acid, sulfuric acid and acetic acid.

Examples of the compound represented by the formula (4) include the following compounds.

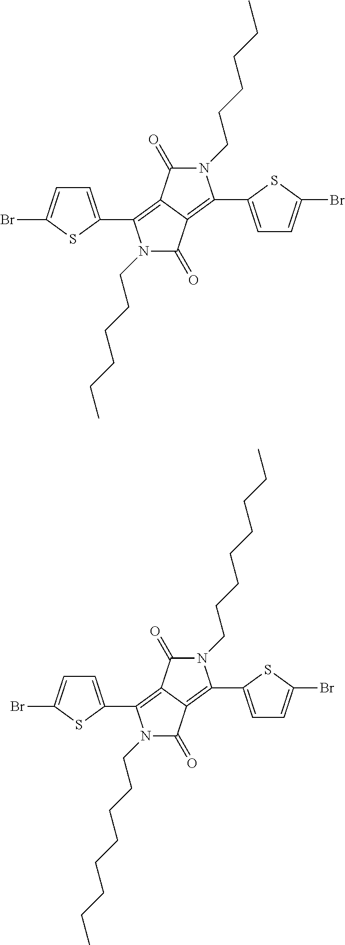 [SMILES: CCCCCCN1C(=O)C2=C(c3ccc(Br)s3)N(CCCCCC)C(=O)C2=C1c1ccc(Br)s1 ; CCCCCCCCN1C(=O)C2=C(c3ccc(Br)s3)N(CCCCCCCC)C(=O)C2=C1c1ccc(Br)s1]

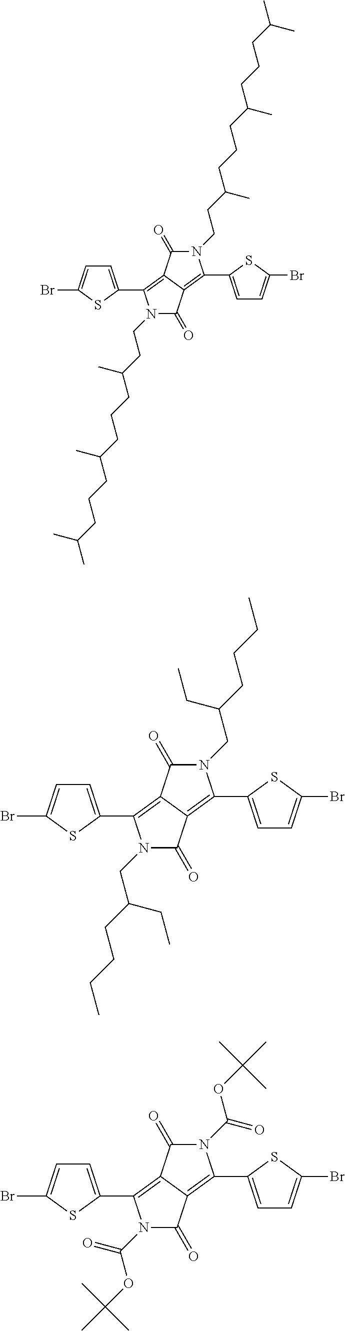 [SMILES: CC(C)CCCC(C)CCCC(C)CCN1C(=O)C2=C(c3ccc(Br)s3)N(CCC(C)CCCC(C)CCCC(C)C)C(=O)C2=C1c1ccc(Br)s1 ; CCCCC(CC)CN1C(=O)C2=C(c3ccc(Br)s3)N(CC(CC)CCCC)C(=O)C2=C1c1ccc(Br)s1 ; CC(C)(C)OC(=O)N1C(=O)C2=C(c3ccc(Br)s3)N(C(=O)OC(C)(C)C)C(=O)C2=C1c1ccc(Br)s1]

Since the polymer compound of the present invention manifests high absorbance of long-wavelength light such as light of 600 nm and the like and thus absorbs solar light efficiently, an organic photoelectric conversion device produced by using the polymer compound of the present invention has increased short circuit current density.

The organic photoelectric conversion device of the present invention has a pair of electrodes and a functional layer between the electrodes, and the functional layer comprises an electron accepting compound and a polymer compound containing a repeating unit represented by the formula (1). As the electron accepting compound, fullerene and fullerene derivatives are preferable. Specific examples of the organic photoelectric conversion device include:

1. organic photoelectric conversion devices having a pair of electrodes and a functional layer between the electrodes, wherein the functional layer comprises an electron accepting compound and a polymer compound containing a repeating unit represented by the formula (1);

2. organic photoelectric conversion devices having a pair of electrodes and a functional layer between the electrodes, wherein the functional layer comprises an electron accepting compound and a polymer compound containing a repeating unit represented by the formula (1), and the electron accepting compound is a fullerene derivative.

In the above-described pair of electrodes, it is usual that at least one of them is transparent or semi-transparent, and this case will be explained as one example below.

In the above-described organic photoelectric conversion device 1, the amount of the electron accepting compound in the functional layer comprising the electron accepting compound and the above-described polymer compound is preferably 10 to 1000 parts by weight, more preferably 20 to 500 parts by weight with respect to 100 parts by weight of the above-described polymer compound. In the above-described organic photoelectric conversion device 2, the amount of the fullerene derivative in the functional layer comprising the fullerene derivative and the above-described polymer compound is preferably 10 to 1000 parts by weight, more preferably 20 to 500 parts by weight with respect to 100 parts by weight of the above-described polymer compound. The amount of the fullerene derivative in the functional layer is preferably 20 to 400 parts by weight, more preferably 40 to 250 parts by weight, further preferably 80 to 120 parts by weight with respect to 100 parts by weight of the above-described polymer compound, from the standpoint of enhancement of photoelectric conversion efficiency. The amount of the fullerene derivative in the functional layer is preferably 20 to 250 parts by weight, more preferably 40 to 120 parts by weight with respect to 100 parts by weight of the above-described polymer compound, from the standpoint of enhancement of short circuit current density.

For the organic photoelectric conversion device to have high photoelectric conversion efficiency, it is important that the above-described electron accepting compound and the polymer compound represented by the formula (1) have an absorption range in which the spectrum of desired incident light can be efficiently absorbed, that the heterojunction interface is contained in large amount in the functional layer so that the heterojunction interface between the above-described electron accepting compound and the polymer compound represented by the formula (1) efficiently separates excitons, and that the above-described electron accepting compound and the polymer compound represented by the formula (1) have charge transportability by which charges generated at the heterojunction interface are transported quickly to the electrode.

From such a standpoint, the above-described organic photoelectric conversion devices 1 and 2 are preferable as the organic photoelectric conversion device, and the above-described organic photoelectric conversion device 2 is more preferable since the heterojunction interface is contained in large amount. In the organic photoelectric conversion device of the present invention, an additional layer may be provided between at least one electrode and the functional layer in the device. Examples of the additional layer include charge transporting layers that transport holes or charges, and the like.

The organic photoelectric conversion device of the present invention is usually formed on a base plate. The base plate may advantageously be one which does not chemically change in forming an electrode and forming a layer of an organic material. Examples of the material of the base plate include glass, plastics, polymer films and silicon materials. In the case of an opaque base plate, it is preferable that the opposite electrode (namely, an electrode remote from the base plate) is transparent or semi-transparent.

As the material of the pair of electrodes, metals, electrically conductive polymers and the like can be used. It is preferable that one of the pair of electrodes is made of a material having low work function. The material of the electrode includes metals of lithium, sodium, potassium, rubidium, cesium, magnesium, calcium, strontium, barium, aluminum, scandium, vanadium, zinc, yttrium, indium, cerium, samarium, europium, terbium, ytterbium and the like, and alloys composed of two or more metals among the above-described metals or alloys composed of at least one metal among the above-described metals and at least one metal among gold, silver, platinum, copper, manganese, titanium, cobalt, nickel, tungsten and tin, graphite, graphite intercalation compounds and the like. Examples of the alloy include a magnesium-silver alloy, a magnesium-indium alloy, a magnesium-aluminum alloy, an indium-silver alloy, a lithium-aluminum alloy, a lithium-magnesium alloy, a lithium-indium alloy and a calcium-aluminum alloy.

The material of the above-described transparent or semi-transparent electrode include electrically conductive metal oxide films, semi-transparent metal thin films and the like. Specifically, use is made of films fabricated using electrically conductive materials composed of indium oxide, zinc oxide, tin oxide, and composites thereof: indium-tin-oxide (ITO), indium.zinc.oxide and the like, and NESA, gold, platinum, silver and copper, and preferable are ITO, indium-zinc-oxide and tin oxide. The electrode fabrication method includes a vacuum vapor deposition method, a sputtering method, an ion plating method, a plating method and the like. Further, organic transparent electrically conductive films made of polyaniline and derivatives thereof, polythiophene and derivatives thereof and the like may also be used as the electrode material.

As the material used in a charge transporting layer, that is a hole transporting layer or an electron transporting layer, as the above-described additional layer, electron donative compounds and electron accepting compounds described later can be used, respectively.

As the material used in a buffer layer as the additional layer, halides or oxides and the like of alkali metals or alkaline earth metals such as lithium fluoride and the like can be used. Further, fine particles made of inorganic semiconductors such as titanium oxide and the like can also be used.

As the above-described functional layer in the organic photoelectric conversion device of the present invention, for example, organic thin films containing the polymer compound of the present invention can be used.

The above-described organic thin film has a thickness of usually 1 nm to 100 μm, preferably 2 nm to 1000 nm, more preferably 5 nm to 500 nm, further preferably 20 nm to 200 nm.

The above-described organic thin film may contain the above-described polymer compound singly or contain two or more of the polymer compound in combination. For enhancing the hole transportability of the above-described organic thin film, low molecular weight compounds and/or polymer compounds other than the above-described polymer compound can also be used in admixture as the electron donative compound in the above-described organic thin film.

Examples of the electron donative compound which may be contained in the organic thin film in addition to the above-described polymer compound having a repeating unit represented by the formula (1) include pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having an aromatic amine on the side chain or main chain, polyaniline and derivatives thereof, polythiophene and derivatives thereof, polypyrrole and derivatives thereof, polyphenylenevinylene and derivatives thereof and polythienylenevinylene and derivatives thereof.

Examples of the above-described electron accepting compound include oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ and the like and derivatives thereof, carbon nanotube, and phenanthroline derivatives such as 2,9-dimethyl-4,7-diphenyl-1,10-phenanthroline and the like, and especially preferable are fullerene and derivatives thereof.

The above-described electron donative compounds and the above-described electron accepting compounds are determined relatively according to the energy level of these compounds.

The fullerene and derivatives thereof include C₆₀, C₇₀, C₈₄ and derivatives thereof. The fullerene derivative denotes a compound obtained by modifying at least part of fullerene.

Examples of the fullerene derivative include compounds represented by the formula (I), compounds represented by the formula (II), compounds represented by the formula (III) and compounds represented by the formula (IV).

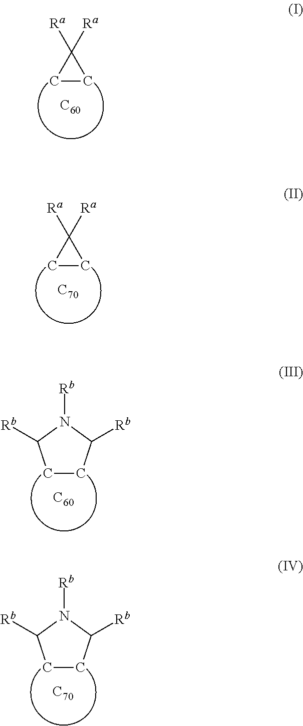

(in the formulae (1) to (IV), R^{a} represents an alkyl group, an optionally substituted aryl group, an optionally substituted heteroaryl group or a group having an ester structure. A plurality of R^{a}s may be the same or mutually different. R^{b} represents an alkyl group or an optionally substituted aryl group. A plurality of R^{b}s may be the same or mutually different.)

The definitions and specific examples of the alkyl group, optionally substituted aryl group and optionally substituted heteroaryl group represented by R^{a} and R^{b} are the same as those of the alkyl group, optionally substituted aryl group and optionally substituted heteroaryl group represented by R.

The group having an ester structure represented by R^{a} includes, for example, groups represented by the formula (V).

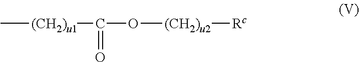

(wherein, u1 represents an integer of 1 to 6, u2 represents an integer of 0 to 6 and R^{c} represents an alkyl group, an optionally substituted aryl group or an optionally substituted heteroaryl group.)

The definitions and specific examples of the alkyl group, optionally substituted aryl group and optionally substituted heteroaryl group represented by R^{c} are the same as those of the alkyl group, optionally substituted aryl group and optionally substituted heteroaryl group represented by R.

Specific examples of the derivative of C₆₀ include the following compounds.

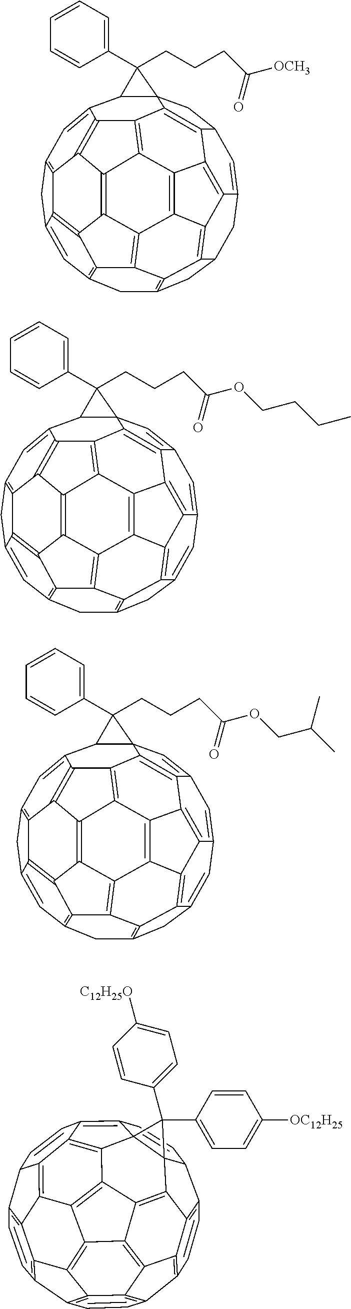

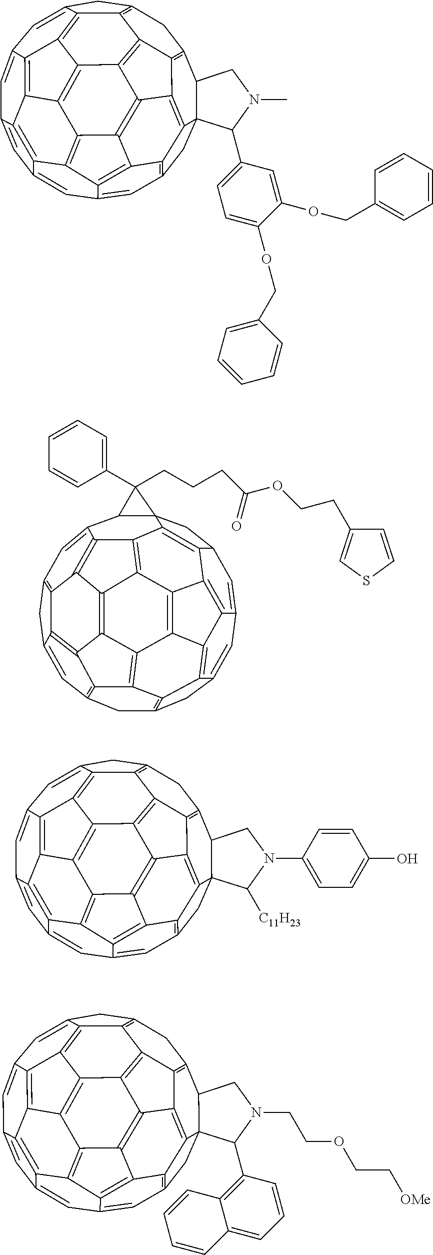

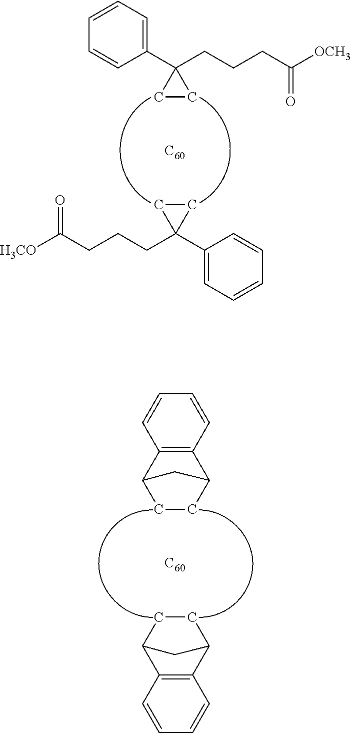 [SMILES: COC(=O)CCCC1(c2ccccc2)CC1 ; "C60" ; COC(=O)CCCC1(c2ccccc2)CC1 ; c1ccc2c(c1)C1CCC2C1 ; "C60" ; c1ccc2c(c1)C1CCC2C1]

Specific examples of the derivative of C₇₀ include the following compounds.

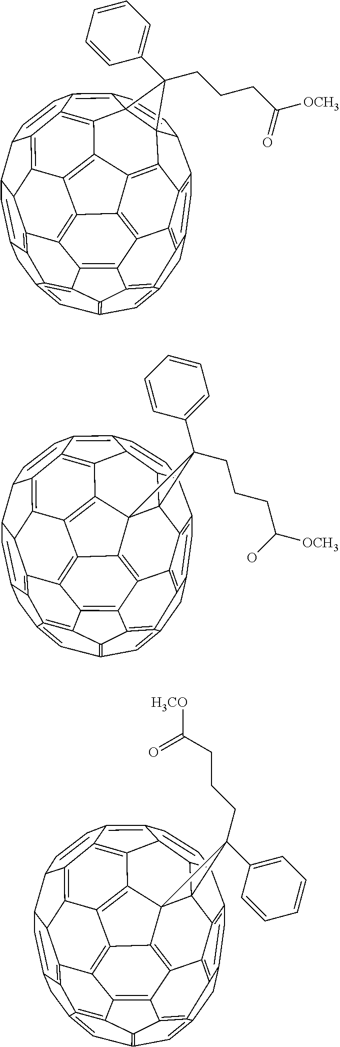 [SMILES: COC(=O)CCCC1(c2ccccc2)C23C4=C5C=CC6c7c5c2c2c5c7C7c8c9c%10c(cc%11cc%12c%13c%14c(cc%15c%16c(c2c2c5c8c5c%10c%11c%13c5c2c%16%14)C13C%15C=C4)C%12)CC9=CC67 ; COC(O)CCCC1(c2ccccc2)C23c4c5c6c7c8c4C4C9=C8C=CC7C7C=C8Cc%10cc%11cc%12c%13c%14c(cc%15c(c%14c%14c2c-5c2c(c8c%10c5c%11c%13c%14c25)C67)C13C4C%15C=C9)C%12 ; COC(=O)CCCC1(c2ccccc2)C23c4c5c6c7c8c4C4C9=C8C=CC7C7C=C8Cc%10cc%11cc%12c%13c%14c(cc%15c(c%14c%14c2c-5c2c(c8c%10c5c%11c%13c%14c25)C67)C13C4C%15C=C9)C%12]

The above-described organic thin film may be produced by any methods and, for example, may be produced by a method according to film formation from a solution containing the polymer compound of the present invention, or an organic thin film may be formed by a vacuum vapor deposition method. The method of producing an organic thin film according to film formation from a solution includes, for example, a method of coating the solution on one electrode, then, evaporating the solvent, to produce the organic thin film.

The solvent to be used in film formation from a solution is not particularly restricted providing it can dissolve the polymer compound of the present invention. Examples of this solvent include hydrocarbon solvents such as toluene, xylene, mesitylene, tetralin, decalin, bicyclohexyl, butylbenzene, sec-butylbenzene, tert-butylbenzene and the like, halogenated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane, chlorobenzene, dichlorobenzene, trichlorobenzene and the like, and ether solvents such as tetrahydrofuran, tetrahydropyran and the like. Usually, the polymer compound of the present invention can be dissolved in an amount of 0.1 wt % or more in the above-described solvent.

For film formation from a solution, use can be made of coating methods such as a spin coating method, a casting method, a micro gravure coating method, a gravure coating method, a bar coating method, a roll coating method, a wire bar coating method, a dip coating method, a spray coating method, a screen printing method, a flexo printing method, an offset printing method, an inkjet printing method, a dispenser printing method, a nozzle coating method, a capillary coating method and the like, and preferable are a spin coating method, a flexo printing method, an inkjet printing method and a dispenser printing method.

The organic photoelectric conversion device can be irradiated with light such as solar light or the like on the transparent or semi-transparent electrode, thereby generating photovoltaic power between the electrodes, thus, the organic photoelectric conversion device can be functioned as an organic thin film solar battery. It is also possible that pluralities of organic thin film solar batteries are accumulated and these are used as an organic thin film solar battery module.

Under application of voltage between the electrodes, the transparent or semi-transparent electrodes can be irradiated with light, thereby causing flow of photocurrent, thus, the device can be functioned as an organic optical sensor. It is also possible that pluralities of organic optical sensors are accumulated and these are used as an organic image sensor.

### EXAMPLES

Examples will be shown below for illustrating the present invention further in detail, but the present invention is not limited to them.

The polystyrene-equivalent weight-average molecular weight of a polymer compound was determined by size exclusion chromatography (SEC).

Column: TOSOH TSKgel SuperHM-H (two columns)+TSKgel SuperH2000 (4.6 mm I.d.×15 cm); Detector: RI (SHIMADZU RID-10A); mobile phase: tetrahydrofuran (THF)

### Synthesis Example 1

### Synthesis of Compound (B)

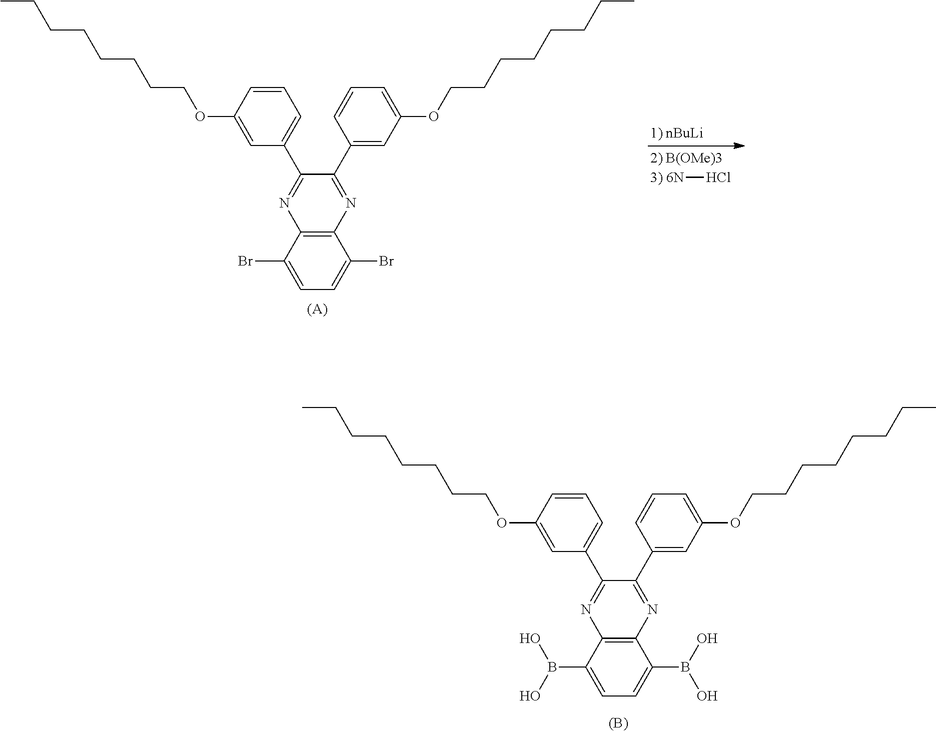

Under a nitrogen atmosphere, into a 100 ml three-necked flask equipped with a Dimroth condenser were charged 3.1 g (4.5 mmol) of a compound (A) synthesized by a method described in Adv. Funct. Mater., 2007, vol. 17, pp. 3836-3842 and 50 ml of anhydrous tetrahydrofuran (THF), and the mixture was stirred at −78° C. While keeping the temperature in the flaks at −70° C. or lower, 5.9 ml (9.3 mmol) of a 1.57 M butyllithium (n-BuLi) hexane solution was dropped, and the mixture was stirred for 1 hour. Thereafter, 1.0 g (9.6 mmol) of trimethoxyborane was dropped into the flask and the mixture was stirred for 30 minutes, then, heated up to room temperature (25° C.), and stirred for 5 hours. Thereafter, 50 ml of water was added and the mixture was extracted with 100 ml of diethyl ether twice. The resultant organic layer was concentrated by an evaporator, then, to the concentrated solution were added 50 ml of chloroform and 50 ml of 6N hydrochloric acid, and the mixture was stirred at room temperature (25° C.) for 5 hours. After allowing to stand still for 1 hour, the mixture was filtrated and the resultant solid was dried under reduced pressure (30 mmHg, 80° C.) for 5 hours, to obtain 0.74 g of a compound (B). The compound (B) was used in the next reaction without purification thereof. The yield of the compound (B) was 26%.

### Synthesis Example 2

### Synthesis of Compound (C)

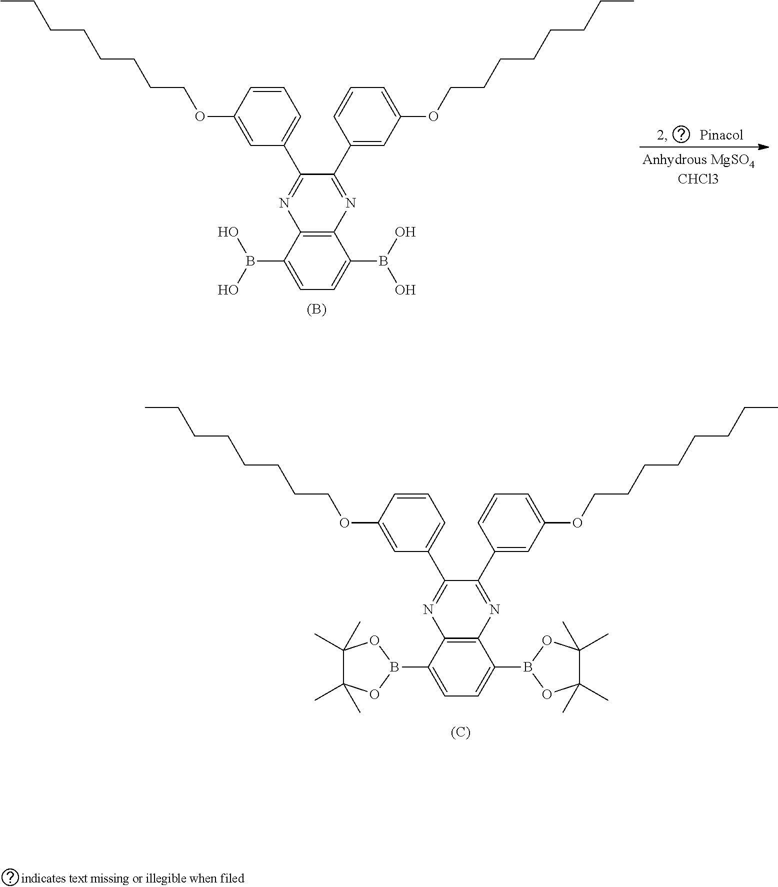

Into a 100 ml three-necked flask were charged 0.74 g (1.2 mmol) of the compound (B), 0.29 g (2.5 mmol) of pinacol and 30 ml of chloroform at room temperature (25° C.), and the mixture was stirred while refluxing with heat until the slurry reaction solution became homogeneous. Thereafter, 1.0 g of anhydrous magnesium sulfate was added to the reaction solution, and the mixture was further stirred for 4 hours while refluxing with heat. After stirring, the mixture was filtrated, and the filtrate was concentrated by an evaporator. After concentration, the residue was washed with 20 ml of hexane, and the resultant crystal was filtrated and collected, and dried under reduced pressure (50 mmHg, 30° C.) for 3 hours, to obtain 0.57 g (0.73 mmol) of a compound (C). The yield of the compound (C) was 62%.

¹H-NMR (270 MHz/CDCl₃):

δ7.99 (s, 2H), 7.39 (brs, 2H), 7.15 (m, 4H), 6.87 (m, 2H), 3.88 (t, 4H), 1.77-1.66 (m, 4H), 1.47 (s, 24H), 1.50-1.20 (m, 24H), 0.89 (t, 6H)

### Example 1

### Synthesis of Polymer Compound 1

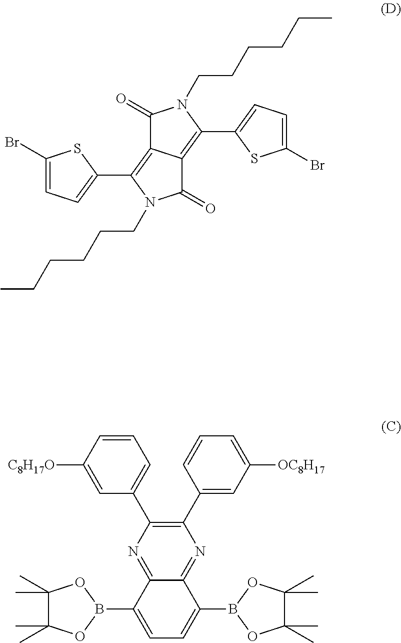

Under an argon atmosphere, into a reaction vessel were added 99 mg (0.158 mmol) of a compound (D) (manufactured by Luminescence Technology Corporation), 120 mg (0.152 mmol) of the compound (C), 55 mg of trioctylmethylammonium chloride (trade name: Aliquat336 (registered trademark), manufactured by Sigma-Aldrich) and 11 mL of toluene. The resultant solution was bubbled with argon, to attain sufficient deaeration. To the reaction solution were added 0.53 mg (0.00236 mmol) of palladium acetate, 2.90 mg (0.00823 mmol) of tris(methoxyphenyl)phosphine and 1.1 mL of a deaerated 16.7 wt % sodium carbonate aqueous solution, and the mixture was refluxed for 6 hours. Next, to the resultant reaction solution was added 14.0 mg of phenylboric acid, then, the mixture was refluxed for 2 hours. Thereafter, 10 mL of a 9.1 wt % sodium diethyldithiocarbamate aqueous solution was added, and the mixture was refluxed for 5 hours. After completion of reflux, the reaction solution was cooled down to room temperature (25° C.), and the reaction solution was poured into methanol. The precipitate was filtrated and collected, and washed with 50 mL of water twice and with 50 mL of methanol twice, then, dried to obtain 82 mg of a polymer compound 1.

### Synthesis Example 3

### Synthesis of Polymer Compound 2

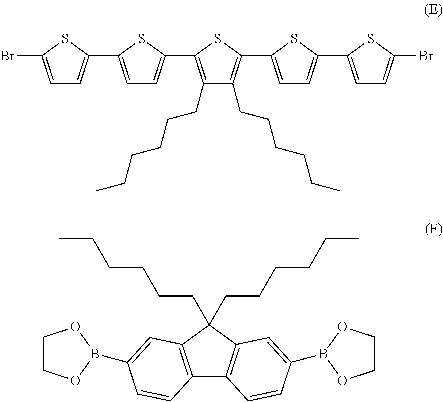 [SMILES: CCCCCCc1c(-c2ccc(-c3ccc(Br)s3)s2)sc(-c2ccc(-c3ccc(Br)s3)s2)c1CCCCCC ; CCCCCCC1(CCCCCC)c2cc(B3OCCO3)ccc2-c2ccc(B3OCCO3)cc21]

Into a 2 L four-necked flask of which internal gas had been purged with argon were charged 7.928 g (16.72 mmol) of the compound (E), 13.00 g (17.60 mmol) of the compound (F), 4.979 g of trioctylmethylammonium chloride (trade name: Aliquat336 (registered trademark), manufactured by Sigma-Aldrich, CH₃N[(CH₂)₇CH₃]₃Cl, density 0.884 g/ml, 25° C.) and 405 ml of toluene, and the reaction system was bubbled with argon for 30 minutes while stirring. Into the flask was added 0.02 g of dichlorobis(triphenylphosphine)palladium(II), the mixture was heated up to 105° C., and 42.2 ml of a 2 mol/L sodium carbonate aqueous solution was dropped while stirring. After completion of dropping, the mixture was reacted for 5 hours, and then, 2.6 g of phenylboronic acid and 1.8 ml of toluene were added, and the mixture was stirred at 105° C. for 16 hours. Thereafter, to the reaction solution were added 700 ml of toluene and 200 ml of a 7.5 wt % sodium diethyldithiocarbamate trihydrate aqueous solution, and the mixture was stirred at 85° C. for 3 hours. The aqueous layer of the reaction solution was removed, then, the organic layer was washed with 300 ml of ion exchanged water of 60° C. twice, with 300 ml of 3 wt % acetic acid of 60° C. once, further with 300 ml of ion exchanged water of 60° C. three times. The organic layer was allowed to pass through a column filled with celite, alumina and silica, and the filtrate was recovered. Thereafter, the column was washed with 800 ml of hot toluene, and the toluene solution after washing was added to the filtrate. The resultant solution was concentrated to 700 ml, then, the concentrated solution was added to 2 L of methanol, to cause re-precipitation of a polymer. The polymer was filtrated and collected, and washed with 500 ml of methanol, 500 ml of acetone and 500 ml of methanol. The polymer was vacuum-dried overnight at 50° C. to obtain 12.21 g of a pentathienyl-fluorene copolymer (polymer compound 2). The polystyrene-equivalent weight-average molecular weight of the polymer compound 2 was 1.1×10⁵.

### Synthesis Example 4

### Synthesis of Compound (H)

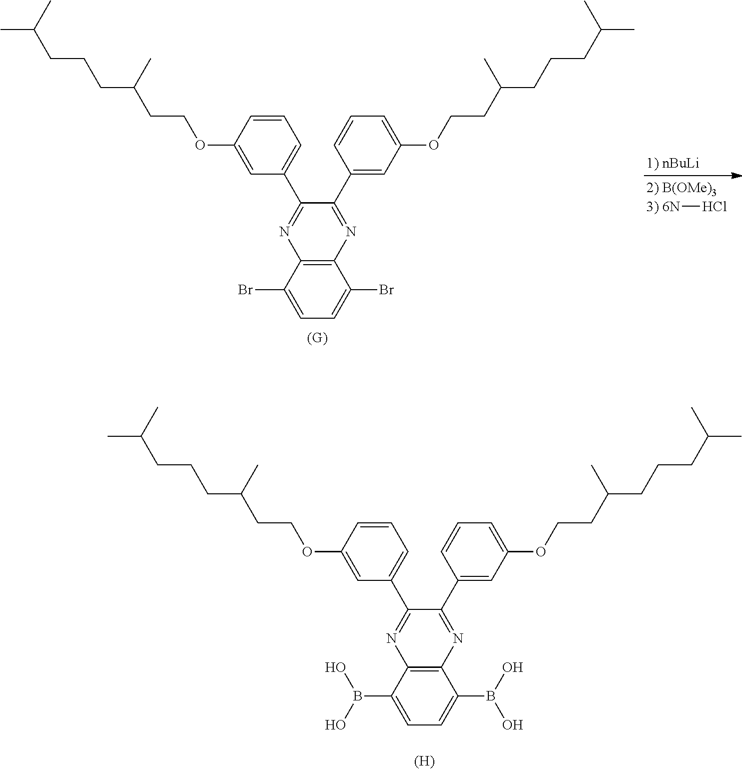

Under a nitrogen atmosphere, into a 100 ml three-necked flask equipped with a Dimroth condenser were added 2.98 g (4.0 mmol) of a compound (G) synthesized by a method described in Adv. Funct. Mater., 2007, vol. 17, pp. 3836-3842 and 70 ml of anhydrous THF, and the mixture was stirred at −78° C. While keeping the temperature in the flaks at −70° C. or lower, 5.3 ml (8.3 mmol) of a 1.57M butyl lithium (n-BuLi) hexane solution was dropped, and the mixture was stirred for 1 hour. Into the reaction solution, 0.9 g (8.7 mmol) of trimethoxyborane was dropped, and the mixture was stirred for 30 minutes, then, heated up to room temperature and stirred for 5 hours. To the reaction solution was added 50 ml of water, the mixture was extracted with 100 ml of diethyl ether twice, the organic layer was concentrated by an evaporator, then, 50 ml of chloroform and 50 ml of 6N hydrochloric acid water were added, and the mixture was stirred at room temperature for 5 hours. After allowing to stand still for 1 hour, the mixture was filtrated to obtain a solid, which was dried under reduced pressure (30 mmHg, 80° C.) to 5 hours, to obtain 1.24 g of a compound (H). The yield of the compound (H) was 45.9%. The compound (H) was used as it was in the next reaction.

### Synthesis Example 5

### Synthesis of Compound (I)

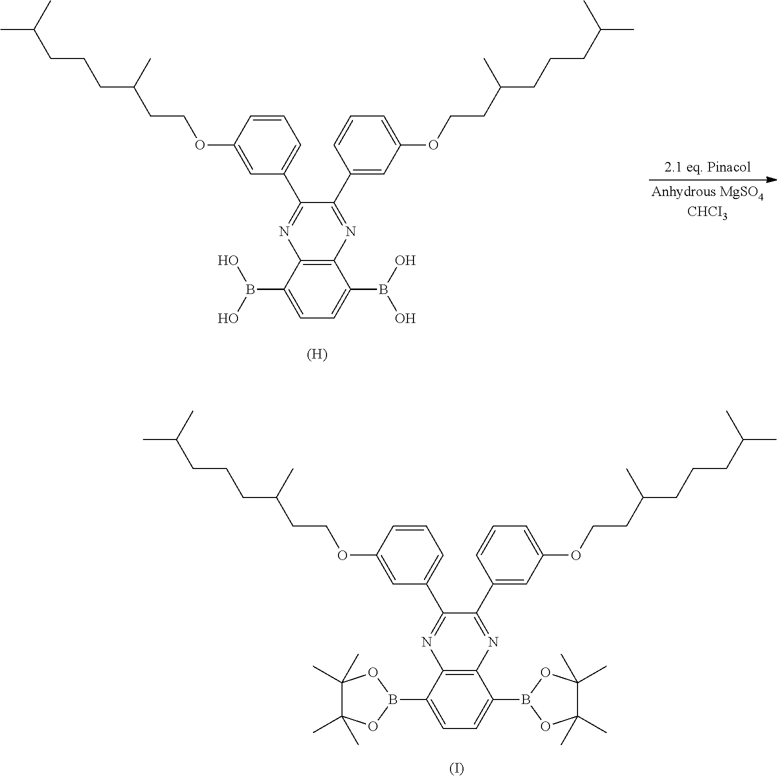

Into a 100 ml three-necked flask were added 1.24 g (1.8 mmol) of the compound (H), 0.44 g (3.7 mmol) of pinacol and 50 ml of chloroform at room temperature, and the mixture was stirred while refluxing with heat until the reaction solution changed from a slurry to a homogenous solution. After confirming that the reaction solution was a homogeneous solution, 1.0 g of anhydrous magnesium sulfate was added, and the mixture was further stirred for 4 hours while refluxing with heat. After stirring, the mixture was filtrated, and the resultant solution was concentrated by an evaporator. The resultant residue was washed with 20 ml of hexane, and the resultant crystal was filtrated and dried under reduced pressure (50 mmHg, 30° C.) for 3 hours, to obtain 1.03 g (1.2 mmol) of a compound (I). The yield of the compound (I) was 66.9%.

¹H-NMR (270 MHz/CDCl₃):

δ7.99 (s, 2H), 7.36 (brs, 2H), 7.18-7.15 (m, 4H), 7.87 (m, 2H), 3.87 (t, 4H), 1.90-1.70 (m, 2H), 1.70-1.45 (m, 2H), 1.40-1.10 (m, 16H), 0.89 (t, 6H), 0.87 (t, 12H)

### Example 2

### Synthesis of Polymer Compound 3

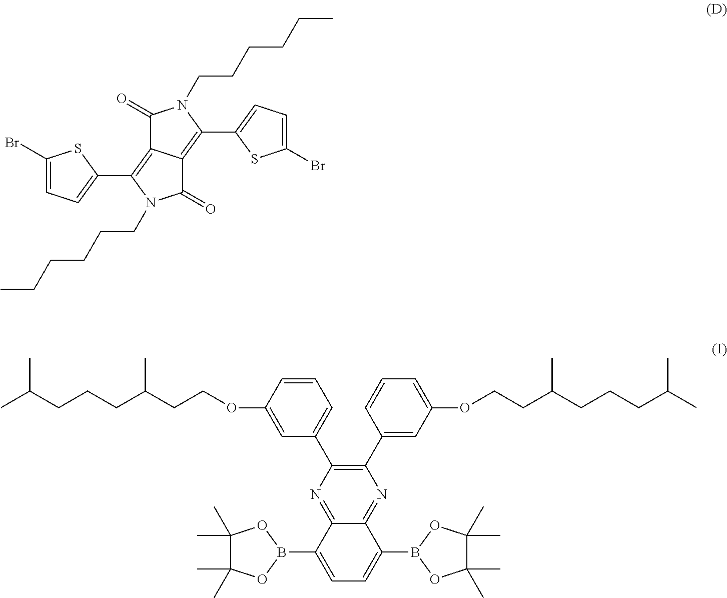 [SMILES: CCCCCCN1C(=O)C2=C(c3ccc(Br)s3)N(CCCCCC)C(=O)C2=C1c1ccc(Br)s1 ; CC(C)CCCC(C)CCOc1cccc(-c2nc3c(B4OC(C)(C)C(C)(C)O4)ccc(B4OC(C)(C)C(C)(C)O4)c3nc2-c2cccc(OCCC(C)CCCC(C)C)c2)c1]

Under an argon atmosphere, into a reaction vessel were charged 89 mg (0.142 mmol) of a compound (D) (manufactured by Luminescence Technology Corporation), 120 mg (0.142 mmol) of the compound (I), 52 mg of trioctylmethylammonium chloride (trade name: Aliquat336 (registered trademark), manufactured by Sigma-Aldrich) and 10 mL of toluene. The resultant solution was bubbled with argon, to attain sufficient deaeration. Further, into the reaction vessel were charged 0.48 mg (0.00214 mmol) of palladium acetate, 2.60 mg (0.00738 mmol) of tris(methoxyphenyl)phosphine and 1.0 mL of a deaerated 16.7 wt % sodium carbonate aqueous solution, and the mixture was refluxed for 6 hours. Next, to the resultant reaction solution was added 9.0 mg of phenylboric acid, and the mixture was refluxed for 2 hours. Thereafter, to the reaction solution was added 10 mL of a 9.1 wt % sodium diethyldithiocarbamate aqueous solution, and the mixture was refluxed for 5 hours. After completion of reflux, the reaction solution was cooled down to room temperature (25° C.), then, the solution was poured into methanol. The precipitate was filtrated and collected and washed with 50 mL of water twice and with 50 mL of methanol twice, then, dried to obtain 54 mg of a polymer compound 3.

### Synthesis Example 6

### Synthesis Example of Compound (L)

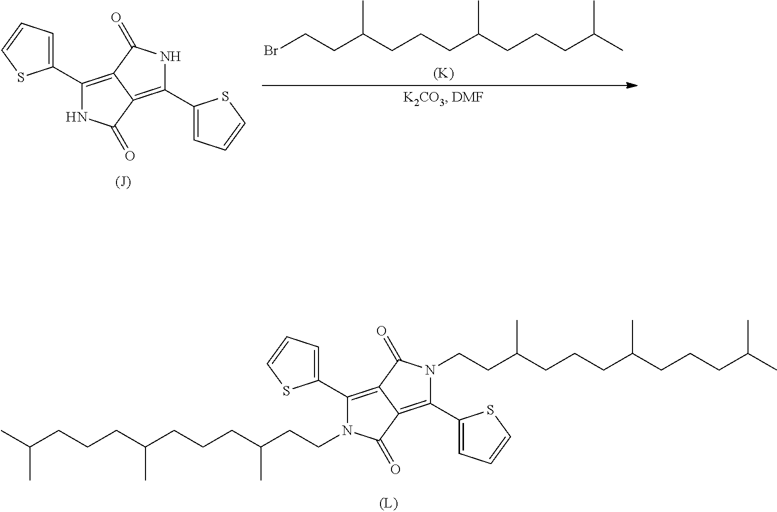

Under a nitrogen atmosphere, into a 100 ml three-necked flask equipped with a Dimroth condenser were charged 1.20 g (4.0 mmol) of a compound (J) obtained by a method described in Macromolecules, 2009, vol. 42, pp. 6564-6571, 2.2 g (16.0 mmol) of anhydrous potassium carbonate and 25 ml of anhydrous N,N-dimethylformamide, and the mixture was heated up to 145° C. Subsequently, 4.07 g (14.0 mmol) of a compound (K) as an alkyl halide was added, and the mixture was stirred at the same temperature for 15 hours with heating. The reaction solution was cooled down to room temperature, then, poured into 50 ml of ice water, and the generated solid was filtrated and collected. The resultant solid was washed with 10 ml of water three times and with 10 ml of methanol three times, then, dried under reduced pressure (30 mmHg, 80° C.) for 5 hours, to obtain a coarse product. The coarse product was purified by silica gel chromatography using dichloromethane as a developer, to obtain 0.60 g of a compound (L). The yield of the compound (L) was 20.8%.

¹H-NMR (270 MHz/CDCl₃):

δ8.91 (dd, 2H), 7.63 (d, 2H), 7.28 (dd, 2H), 4.15-4.05 (m, 4H), 1.80-1.00 (m, 34H), 1.00 (d, 6H), 0.86 (d, 12H), 0.83 (d, 6H)

### Synthesis Example 7

### Synthesis of Compound (M)

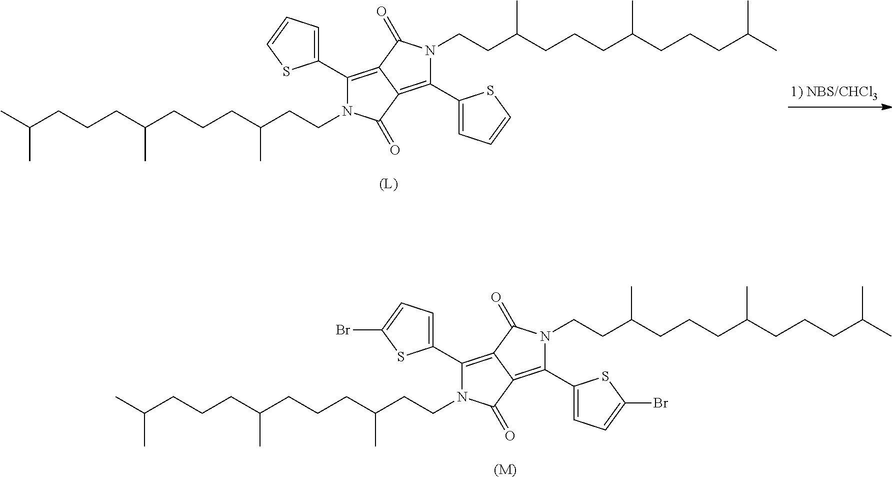

Under light shielding, into a 100 ml three-necked flask were charged 0.60 g (0.83 mmol) of the compound (L), 20 ml of chloroform and 0.30 g (1.70 mmol) of N-bromosuccinimide at room temperature, and the mixture was stirred at the same temperature for 40 hours. After stirring, the solid was filtrated, and the resultant solid was washed with 50 ml of hot methanol (50° C.) twice. The resultant crystal was filtrated and collected, and dried under reduced pressure (50 mmHg, 30° C.) for 3 hours, to obtain 114 mg (0.13 mol) of a compound (M). The yield of the compound (M) was 15.6%.

¹H-NMR (270 MHz/CDCl₃):

δ8.66 (d, 2H), 7.23 (d, 2H), 4.12-3.90 (m, 4H), 1.80-0.90 (m, 34H), 1.00 (d, 6H), 0.86 (d, 12H), 0.83 (d, 6H)

### Example 3

### Synthesis of Polymer Compound 4

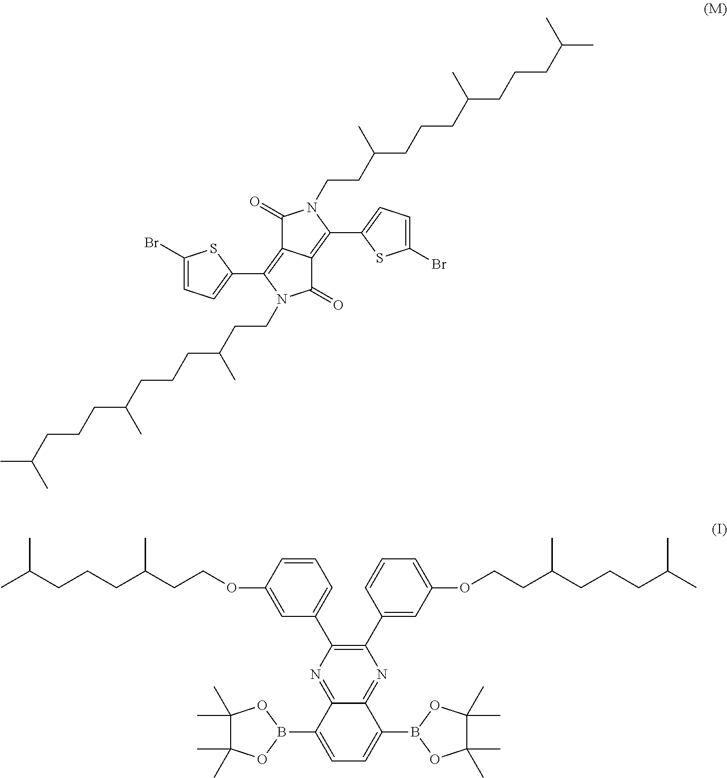

Under an argon atmosphere, into a reaction vessel were charged 44 mg (0.05 mmol) of the compound (M), 46 mg (0.054 mmol) of the compound (I), 0.5 g of trioctylmethylammonium chloride (trade name: Aliquat336 (registered trademark), manufactured by Sigma-Aldrich), 0.6 mg (0.0027 mmol) of palladium acetate, 0.9 mg (0.0026 mmol) of tris(methoxyphenyl)phosphine and 10 mL of deaerated toluene, and the mixture was heated up to 105° C., and 0.3 mL of a deaerated 16.7 wt % sodium carbonate aqueous solution was dropped while stirring. After completion of dropping, the mixture was refluxed for 6 hours. Next, to the resultant reaction solution was added 0.6 mg of phenylboric acid, and the mixture was refluxed at 88° C. for 2 hours. Thereafter, to the reaction solution was added 5 mL of a 9.1 wt % sodium diethyldithiocarbamate aqueous solution, and the mixture was refluxed for 2 hours. After completion of reflux, the reaction solution was cooled down to room temperature (25° C.), the aqueous layer of the reaction solution was removed, then, the organic layer was washed with 5 ml of ion exchanged water of 60° C. twice, with 5 ml of 3 wt % acetic acid of 60° C. twice, further with 5 ml of ion exchanged water of 60° C. twice. The resultant organic layer was poured into 100 mL of methanol to cause re-precipitation. The precipitate was filtrated and collected, and washed with 5 mL of methanol twice, then, dried to obtain 48 mg of a polymer compound 4.

### Example 4

### Measurement of Absorbance of Organic Thin Film

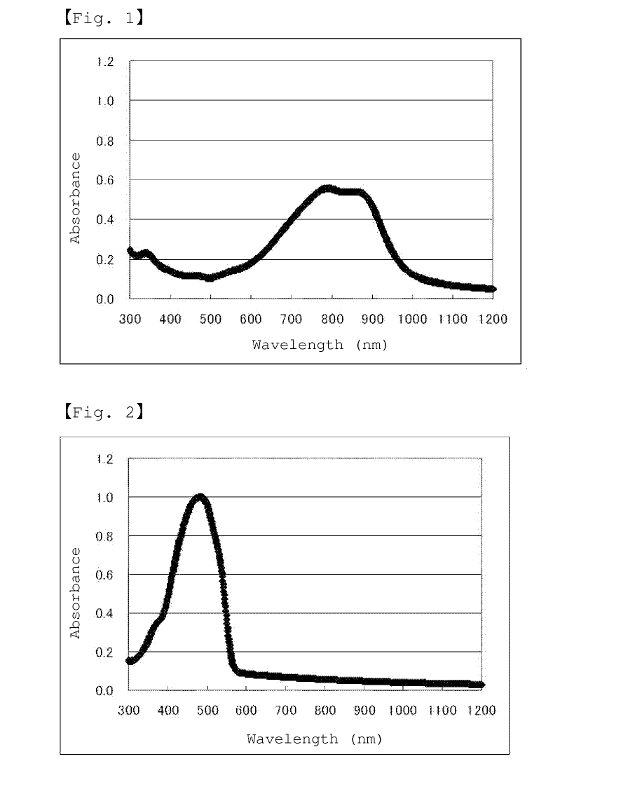

The polymer compound 1 was dissolved at a concentration of 1 wt % in o-dichlorobenzene, to prepare a coating solution. The resultant coating solution was spin-coated on a glass base plate. The coating operation was carried out at 23° C. Thereafter, it was baked for 5 minutes under atmospheric pressure at 120° C., to obtain an organic thin film having a thickness of about 100 nm. The absorption spectrum of the organic thin film was measured by a spectral photometer (manufactured by JASCO Corporation, trade name: V-670). The measured spectrum is shown in FIG. 1. The absorbances at 600 nm, 700 nm, 800 nm and 900 nm are shown in Table 1.

### Comparative Example 1

### Measurement of Absorbance of Organic Thin Film

An organic thin film was fabricated in the same manner as in Example 4 excepting that the polymer compound 2 was used instead of the polymer compound 1, and the absorption spectrum of the organic thin film was measured. The measured spectrum is shown in FIG. 2. The absorbances at 600 nm, 700 nm, 800 nm and 900 nm are shown in Table 1.

### Example 5

### Measurement of Absorbance of Organic Thin Film

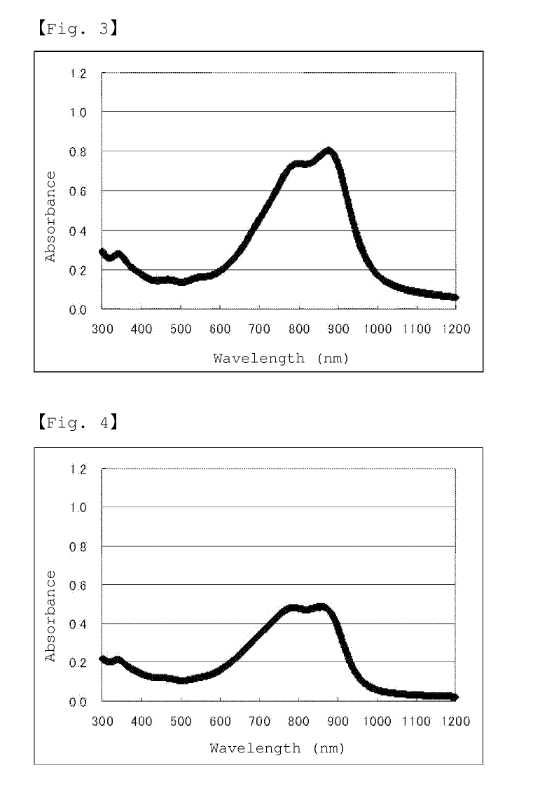

An organic thin film was fabricated in the same manner as in Example 4 excepting that the polymer compound 3 was used instead of the polymer compound 1, and the absorption spectrum of the organic thin film was measured. The measured spectrum is shown in FIG. 3. The absorbances at 600 nm, 700 nm, 800 nm and 900 nm are shown in Table 1.

### Example 6

### Measurement of Absorbance of Organic Thin Film

An organic thin film was fabricated in the same manner as in Example 4 excepting that the polymer compound 4 was used instead of the polymer compound 1, and the absorption spectrum of the organic thin film was measured. The measured spectrum is shown in FIG. 4. The absorbances at 600 nm, 700 nm, 800 nm and 900 nm are shown in Table 1.

TABLE 1

| | | Absorb- | Absorb- | Absorb- | Absorb- |
|---|---|---|---|---|---|
| | Polymer | ance | ance | ance | ance |
| | Compound | at 600 nm | at 700 nm | at 800 nm | at 900 nm |
| Example 3 | Polymer | 0.18 | 0.40 | 0.55 | 0.47 |
| | compound 1 | | | | |
| Example 4 | Polymer | 0.19 | 0.46 | 0.74 | 0.73 |
| | compound 3 | | | | |
| Example 5 | Polymer | 0.16 | 0.35 | 0.48 | 0.38 |
| | compound 4 | | | | |
| Com- | Polymer | 0.09 | 0.07 | 0.06 | 0.05 |
| parative | compound 2 | | | | |
| Example 1 | | | | | |

### Example 7

### Fabrication and Evaluation of Organic Thin Film Solar Battery

A fullerene derivative C60PCBM (Phenyl C61-butyric acid methyl ester, manufactured by Frontier Carbon Corporation, trade name: E100) as an electron accepting compound and the polymer compound 1 as an electron donative compound were mixed at a weight ratio of 3:1, and dissolved in o-dichlorobenzene so that the concentration of the mixture was 2 wt %. The resultant solution was filtrated through a Teflon (registered trademark) filter having a pore diameter of 1.0 μm, to prepare a coating solution 1.

A glass base plate carrying thereon an ITO film with a thickness of 150 nm formed by a sputtering method was treated with ozone-UV, performing a surface treatment. Next, a PEDOT:PSS solution (CleviosP VP AI4083 manufactured by H. C. Starck) was spin-coated on the ITO film, and heated for 10 minutes in atmospheric air at 120° C., to make a hole injection layer having a thickness of 50 nm. Next, the above-described coating solution 1 was spin-coated on the ITO film, to obtain a functional layer of an organic thin film solar battery. The thickness of the functional layer was 100 nm. Thereafter, calcium was vapor-deposited with a thickness of 4 nm, then, aluminum was vapor-deposited with a thickness of 100 nm by a vacuum vapor-deposition machine, to fabricate an organic thin film solar battery. The degree of vacuum in vapor-deposition was constantly 1 to 9×10⁻³ Pa. The shape of thus obtained organic thin film solar battery was 2 mm×2 mm square. The resultant organic thin film solar battery was irradiated with constant light using Solar Simulator (manufactured by BUNKOKEIKI Co. Ltd., trade name: OTENTO-SUNII: AM1.5G filter, irradiance: 100 mW/cm²), and the generating current and volume were measured. The photoelectric conversion efficiency was 2.6%, Jsc (short circuit current density) was 8.5 mA/cm², Voc (open circuit voltage) was 0.64 V and FF (fill factor) was 0.48.

### Example 8

### Fabrication and Evaluation of Organic Thin Film Solar Battery

A coating solution 2 was prepared in the same manner as in Example 7 excepting that the polymer compound 3 was used as the electron donative compound.

An organic thin film solar battery was fabricated in the same manner as in Example 7 excepting that the coating solution 2 was used instead of the coating solution 1. The resultant organic thin film solar battery was irradiated with constant light using Solar Simulator (manufactured by BUNKOKEIKI Co. Ltd., trade name: OTENTO-SUNII: AM1.5G filter, irradiance: 100 mW/cm²), and the generating current and voltage were measured. The photoelectric conversion efficiency was 2.6%, Jsc (short circuit current density) was 9.1 mA/cm², Voc (open circuit voltage) was 0.66V and FF (fill factor) was 0.43.

### INDUSTRIAL APPLICABILITY

The polymer compound of the present invention is useful since it can be used in an organic photoelectric conversion device.

1. A polymer compound comprising a repeating unit represented by the formula (1): 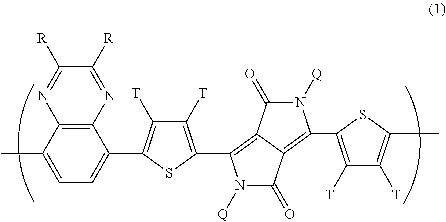
wherein, Q, R and T are the same or different and represent a hydrogen atom, a fluorine atom, an alkyl group optionally substituted by a fluorine atom, an alkoxy group optionally substituted by a fluorine atom, an optionally substituted aryl group, an optionally substituted heteroaryl group or a group represented by the formula (2). Two Qs may be the same or different. Two Rs may be the same or different. Four Ts may be the same or different. 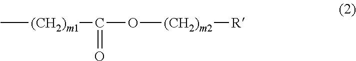
wherein, m1 represents an integer of 0 to 6 and m2 represents an integer of 0 to 6. R′ represents an alkyl group, an optionally substituted aryl group or an optionally substituted heteroaryl group.

2. An organic photoelectric conversion device having a pair of electrodes and a functional layer disposed between the electrodes, wherein the functional layer comprises an electron accepting compound and the polymer compound as described in claim 1.

3. The organic photoelectric conversion device according to claim 2, wherein the amount of the electron accepting compound comprised in the functional layer is 10 to 1000 parts by weight with respect to 100 parts by weight the polymer compound.

4. The organic photoelectric conversion device according to claim 2, wherein the electron accepting compound is a fullerene derivative.

5. The organic photoelectric conversion device according to claim 3, wherein the electron accepting compound is a fullerene derivative.
